(19) United States
(12) Patent Application Publication
(10) Pub. No.: US 2014/0083612 A1
(43) Pub. Date: Mar. 27, 2014

(54) BAFFLE AND METHOD FOR TREATING SURFACE OF THE BAFFLE, AND SUBSTRATE TREATING APPARATUS AND METHOD FOR TREATING SURFACE OF THE APPARATUS

(71) Applicant: PSK INC., Gyeonggi-do (KR)

(72) Inventor: YoungYeon JI, Hwaseong-si (KR)

(73) Assignee: PSK INC., Gyeonggi-do (KR)

(21) Appl. No.: 13/963,162

(22) Filed: Aug. 9, 2013

(30) Foreign Application Priority Data
Sep. 24, 2012 (KR) 10-2012-0105880

(51) Int. Cl. H01L 21/02

(52) U.S. Cl. CPC H01L 21/02041
USPC 156/345.33; 134/1.1; 138/37; 118/723 R; 156/345.1; 156/345.43

(57) ABSTRACT

Provided is a baffle. The baffle has holes for distributing a process gas excited in a plasma state. A surface of the baffle is treated by using a surface treating material containing an aromatic compound.

### CROSS-REFERENCE TO RELATED APPLICATIONS

This U.S. non-provisional patent application claims priority under 35 U.S.C. §119 of Korean Patent Application No. 10-2012-0105880, filed on Sep. 24, 2012, the entire contents of which are hereby incorporated by reference.

### BACKGROUND OF THE INVENTION

The present invention disclosed herein relates to a substrate treating apparatus, and more particularly, to an apparatus for treating a substrate by using plasma.

Plasma represents a state of an ionized gas constituted by ions, electrons, and radicals. Plasma may be generated at a very high temperature or by strong electric fields or radio frequency electromagnetic fields (REEF).

Plasma may be variously applicable to a lithography process in which a photoresist is used to manufacture semiconductor devices. For example, plasma is increasing in utilization in a process of forming various fine circuit patterns such as line or space patterns on a substrate or an asking process of removing a photoresist film used as a mask in an ion implantation process.

A substrate treating apparatus performing an ashing process is disclosed in Korean Patent Registration No. 10-1165725. A plasma source gas may be discharged in a plasma state by induced magnetic fields acting within a reactor, and then the discharged gas may be provided onto a substrate to remove a photoresist film.

While the plasma gas is supplied onto the substrate, active species and radicals contained in the plasma gas may react with a polarized surface of an apparatus and thus be dissipated. The reduction of the active species and radicals may reduce a reaction rate to decrease an ashing rate.

### PRIOR ART DOCUMENT

### Patent Document

Korean Patent Registration No. 10-1165725

### SUMMARY OF THE INVENTION

The present invention provides a substrate treating apparatus which is capable of improving an ashing rate.

The feature of the present invention is not limited to the aforesaid, but other features not described herein will be clearly understood by those skilled in the art from descriptions below.

The feature of the present invention is not limited to the aforesaid, but other features not described herein will be clearly understood by those skilled in the art from descriptions below.

Embodiments of the present invention provide baffles having holes for distributing a process gas excited in a plasma state, wherein a surface of each of the baffles is treated by using a surface treating material containing an aromatic compound.

In some embodiments, the baffle may include: a base in which the holes are defined; and a coupling part having a ring shape, the coupling part protruding upward from an edge of a top surface of the base, wherein the surface treating material is treated on a bottom surface of the base.

In other embodiments, the surface treating material may further include an aliphatic compound.

In still other embodiments, the aromatic compound may include toluene.

In even other embodiments, the surface-treated surface of the baffle may be in a non-polarized state.

In other embodiments of the present invention, substrate treating apparatuses include: a process camber having an inner space; a susceptor disposed within the process chamber to support a substrate; and a process gas supply unit supplying a process gas having a plasma state into the process chamber, wherein an inner surface of the process chamber is treated by using a surface treating material including an aromatic compound.

In some embodiments, the surface treating material may include an aliphatic compound.

In other embodiments, the surface-treated inner surface of the process chamber may be in a non-polarized state.

In still other embodiments, the substrate treating apparatuses may further include a baffle disposed above the susceptor, the baffle having holes for distributing the process gas, wherein a surface of the baffle is treated by using the surface treating material.

In even other embodiments, a bottom surface of the baffle facing the substrate may be treated.

In yet other embodiments, the surface-treated inner surface of the process chamber may be in a non-polarized state.

In still other embodiments of the present invention, apparatuses for a surface of a baffle include: a treating chamber having an inner space; a support plate on which a baffle is placed, the support plate being disposed within the treating chamber and provided as a lower electrode; an upper electrode disposed above the support plate to face the support plate, the upper electrode generating an electric field in a space between the support plate and the upper electrode; and a surface treating gas supply unit supplying a surface treating gas including an aromatic compound into the space between the support plate and the upper electrode, wherein the surface treating gas is excited in a plasma state by the electric field to treat a surface of the baffle.

In some embodiments, the baffle may include: a base in which holes are defined; and a coupling part having a ring shape, the coupling part protruding upward from an edge of a top surface of the base, wherein the baffle is placed on the support plate so that a bottom surface of the base faces the upper electrode.

In other embodiments, the surface treating gas supply unit may include: a container storing a surface treating material including the aromatic compound; an inert gas supply part injecting an inert gas into the container to press the inside of the container; and a gas supply line connecting the treating chamber to the container, the gas supply line supplying the surface treating gas generated in the container into the treating chamber.

In still other embodiments, the surface treating gas supply unit may include: a container storing a surface treating material including the aromatic compound; a heater heating the inside of the container; and a gas supply line connecting the treating chamber to the container, the gas supply line supplying the surface treating gas generated in the container into the treating chamber.

In even other embodiments, the surface treating gas may include an aliphatic compound.

In yet other embodiments, the apparatuses may further include an exhaust member connected to the treating chamber to exhaust a gas within the treating chamber to the outside.

In even other embodiments of the present invention, surface treating methods in which a process gas excited in a plasma state is supplied toward a baffle mounted in a process chamber, and while the excited process gas passes through holes of the baffle to stay in a space between the baffle and a susceptor on which a substrate is placed, a surface treating gas including an aromatic compound is supplied into the space between the baffle and the susceptor to treat a surface of the baffle and an inner surface of the process chamber.

In some embodiments, the surface treating gas may further include an aliphatic compound.

In other embodiments, the surface treating gas may be supplied at a flow rate of about 1 cc/min to about 10 l/min.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a schematic plan view of substrate treating equipment according to an embodiment of the present invention;

FIG. 2 is a schematic view of a substrate treating apparatus according to an embodiment of the present invention;

FIG. 3 is a view of a surface treating apparatus according to an embodiment of the present invention;

FIG. 4 is a view of a substrate treating apparatus according to another embodiment of the present invention;

FIG. 5 is a graph illustrating ashing rates and uniformities of baffles having different surface states; and

FIG. 6 is a graph illustrating aching rates of a baffle according to surface treating materials before and after surface treatment.

### DETAILED DESCRIPTION OF PREFERRED EMBODIMENTS

The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the thicknesses of layers and regions are exaggerated for clarity.

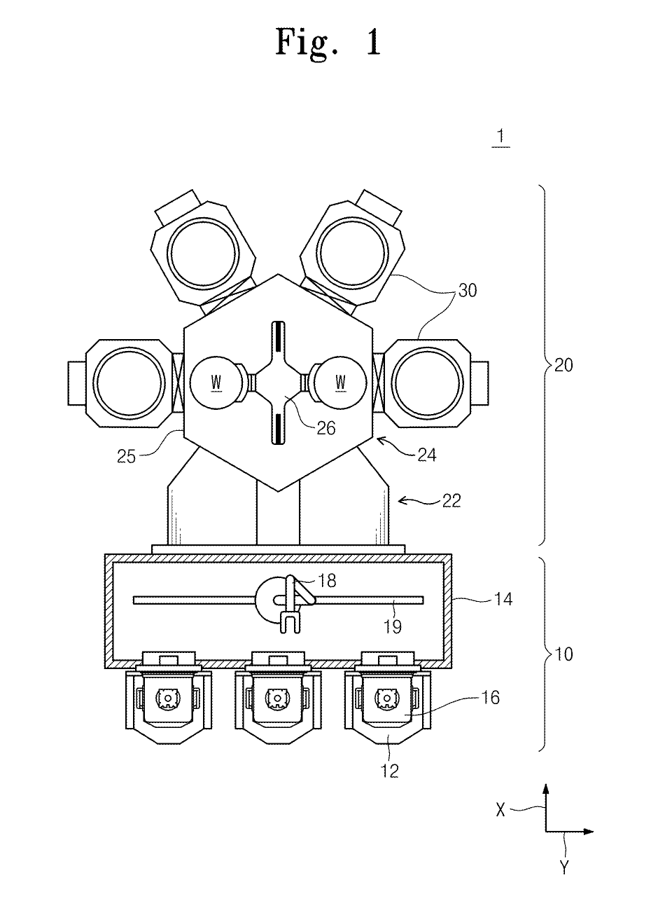

FIG. 1 is a schematic plan view of substrate treating equipment according to an embodiment of the present invention.

Referring to FIG. 1, substrate treating equipment 1 includes an equipment front end module (EFEM) 10 and a process treatment chamber 20. The EFEM 10 and the process treatment chamber 20 are disposed in one direction. Hereinafter, a direction in which the EFEM 10 and the process treatment chamber 20 are arranged is defined as a first direction X. Also, when viewed from an upper side, a direction perpendicular to the first direction X is defined as a second direction Y.

The EFEM 10 is mounted on a front side of the process treatment chamber 20. The EFEM 10 transfers a substrate W between carriers 16 in which substrates are accommodated and the process treatment chamber 20. The EFEM 10 includes a load port 12 and a frame 14.

The load port 12 is disposed on a front side of the frame 14 and is provided in plurality. The plurality of load ports 12 are spaced apart from each other and disposed in a line along the second direction Y. The carriers 16 (e.g., cassettes, a front opening unified pods (FOUPs), and the like) are seated on the load ports 12, respectively. A substrate W to be treated and a treated substrate W are accommodated in each of the carriers 16.

The frame 14 is disposed between the load port 12 and a loadlock chamber 22. A transfer robot 18 for transferring the substrate between the load port 12 and the loadlock chamber 22 is disposed within the frame 14. The transfer robot 18 may be movable along a transfer rail 19 disposed in the second direction Y.

The process treatment chamber 20 includes the loadlock chamber 22, a transfer chamber 24, and a plurality of substrate treating apparatuses 30.

The loadlock chamber 22 is disposed between the transfer chamber 24 and the frame 14. Also, the loadlock chamber 22 provides a space in which the substrate W stands by before the substrate W to be treated is transferred into each of the substrate treating apparatuses 30, or before the treated substrate is transferred into the carrier 16. The loadlock chamber 2 may be provided in one or plurality. According to an embodiment, two loadlock chambers 22 are provided. Here, the substrate W to be loaded into the substrate treating apparatus 30 for performing the substrate treating process may be accommodated in one loadlock chamber 22, and the substrate W that is treated in the substrate treating apparatus 30 may be accommodated in the other loadlock chamber 22.

The transfer chamber 24 is disposed on a rear side of each of the loadlock chambers 22 in the first direction X. When viewed from an upper side, the transfer chamber 24 may include a main body 25 having a polygonal shape when viewed from an upper side. The loadlock chambers 22 and the plurality of substrate treating apparatuses 30 are disposed on the outside of the main body 25 along a circumference of the main body 25 According to an embodiment, the transfer chamber 24 may include a main body having a pentagonal shape when viewed from an upper side. The loadlock chambers 22 are respectively disposed on two sidewalls of the transfer chamber 24 adjacent to the EFEM 10, and the substrate treating apparatuses 30 are respectively disposed on remaining sidewalls of the transfer chamber 24. A passage (not shown) through which the substrate W is loaded or unloaded is defined in each of the sidewalls of the main body 25. The passage may provide a space through which the substrate is loaded or unloaded between the transfer chamber 24 and the loadlock chamber 22 or between the transfer chamber 24 and the substrate treating apparatus 30. A door (not shown) for opening or closing the passage is disposed on the passage. The transfer chamber 24 may have various shapes according to required process modules.

The transfer robot 24 is disposed within the transfer chamber 24. The transfer robot 26 may transfer the non-treated substrate W standing by in the loadlock chamber 22 into the substrate treating apparatus 30 or transfer the substrate W treated in the substrate treating apparatus 30 into the loadlock chamber 22. The transfer robot 26 may successively provide the substrates W into the substrate treating apparatuses 30.

The substrate treating apparatus 30 may supply a gas having a plasma state onto a substrate to perform the substrate treating process. The plasma gas may be variously used in a semiconductor manufacturing process. Although the substrate treating apparatus 30 performs an aching process for removing a photoresist film applied on a substrate in the current embodiment, the present invention is not limited thereto. For example, various processes using plasma such as an etching process and a deposition process may be applied to the substrate treating apparatus 30.

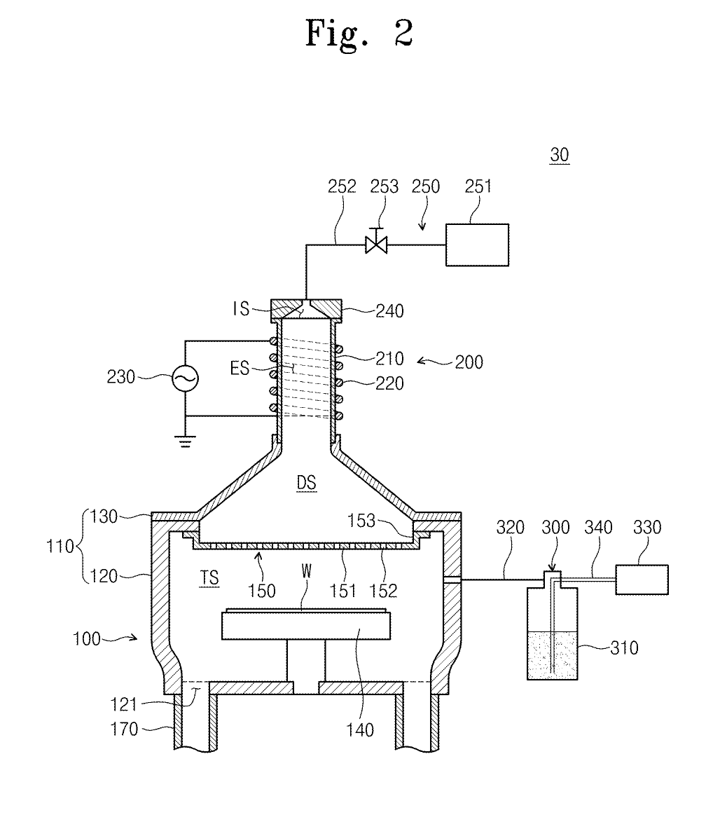

FIG. 2 is a schematic view of the substrate treating apparatus according to an embodiment of the present invention.

Referring to FIG. 2, a substrate treating apparatus 30 includes a process treating unit 100, a plasma supply unit 200, and a surface treating gas supply unit 300.

The process treating unit 100 provides a space in which a substrate treating process is performed. The plasma supply unit 200 generates plasma used in the substrate treating process to supply the generated plasma onto a substrate W in a down stream manner. The surface treating gas supply unit 300 may supply a surface treating gas into the process chamber 110 to treat surfaces of apparatuses provided into the process chamber. Hereinafter, respective constitutions will be described in detail.

The process treating unit 100 includes a process chamber 110, a susceptor 140, and a baffle 150.

The process chamber 110 provides a treating space TS in which a substrate W is treated. The process chamber 110 includes a body 120 and a sealing cover 130. The body 120 may have an opened top surface and an inner shape. An opening (not shown) through which the substrate W is loaded or unloaded is defined in a sidewall of the body 120. The opening may be opened or closed by an opening/closing member such as a slit door (not shown). The opening/closing member may close the opening while the substrate W is treated in the process chamber 110 and open the opening when the substrate W is loaded into and unloaded from the process chamber 110. An exhaust hole 121 is defined in a lower wall of the body 120. The exhaust hole 121 is connected to an exhaust line 170. An inner pressure of the process chamber 110 may be adjusted through the exhaust line 170, and byproducts generated during the process may be discharged to the outside of the process chamber 110 through the exhaust line 170.

The sealing cover 130 is coupled to an upper wall of the body 120 to cover the opened top surface of the body 120, thereby sealing the inside of the body 120. An upper end of the sealing cover 130 is connected to the plasma supply unit 200. An inducing space DS is defined in the sealing cover 130. The inducing space DS has an inverted hopper shape. Plasma supplied from the plasma supply unit 200 is diffused in the inducing space DS to move into the baffle 150.

The susceptor 140 is disposed in a treating space TS to support the substrate W. The susceptor 140 may include an electrostatic for absorbing the substrate W by using an electrostatic force. Lift holes (not shown) may be defined in the susceptor 140. Lift pins (not shown) are disposed in the lift holes, respectively. When the substrate W is loaded on or unloaded from the susceptor 140, the lift pins respectively elevate along the lift holes. A heater (not shown) may be disposed within the susceptor 140. The heater may heat the substrate W to maintain the substrate W at a process temperature.

The baffle 150 is coupled to the upper wall of the body 120 between the body 120 and the sealing cover 130. The baffle 150 may be formed of a metal or dielectric material. For example, the baffle 150 may be formed of a nickel or aluminum material. Alternatively, the baffle may be formed of a quartz or alumina material.

The baffle 150 includes a base 151 and a coupling part 153. The base 151 may have a circular plate shape. The base 151 is disposed parallel to a top surface of the susceptor 140. The base 151 may have an area greater than that of the substrate W. The base 151 may have a flat bottom surface facing the susceptor 140. Holes 152 are defined in the base 151. The plasma diffused in the inducing space DS may pass through the holes 152 and then be introduced into the treating space TS.

The coupling part 154 protrudes upward from an edge of the top surface of the base 151 and has a ring shape. The coupling part 154 may be provided as a region in which the baffle 150 is coupled to the upper wall of the body 120.

The baffle 150 is treated by using a surface treating material. The surface treating material may include an aromatic compound. Since the surface treatment is performed on the surface of the baffle, the surface of the baffle may be maintained in a non-polarized state. The aromatic compound has bonding energy greater than that of an aliphatic compound. For example, in a case of C—C bonding, the aliphatic compound may have bonding energy of about 3.6 eV, and the aromatic compound may have bonding energy of about 15.7 eV.

The aliphatic compound has relatively low bonding energy. Thus, when the aliphatic compound is exposed to the plasma gas, the bonding of the aliphatic compound may be easily dissociated by active species and radicals of the plasma gas. Since the dissociated components are bonded to the active species and radicals, the active species and radicals contained in the plasma gas may be reduced in flow rate. That is, the active species and radicals may be reduced in flow rate to decrease an ashing rate.

On the other hand, since the aromatic compound has relatively high bonding energy, even though the aromatic compound is exposed to the plasma gas, the bonding of the aromatic compound may not be broken. As a result, since the aromatic compound and the plasma gas do not react with each other, the active species and radicals may be maintained in flow rate. Therefore, the ashing rate may be improved.

According to an embodiment, the aromatic compound may be solely provided as the surface treating material. Alternatively, a material containing the aromatic compound and aliphatic compound may be provided as the surface treating material. The aromatic compound may include toluene, benzene, or xylene.

The surface treating material may be surface-treated on a bottom surface of the base 151 in a region of the baffle 150. During a process time, the most plasma gas may stay in a space between the base 151 and the susceptor 140. Since the bottom surface of the base 151 is exposed to the plasma gas during the process time, the surface treating of the bottom surface of the base 151 may be required than other regions of the baffle 150.

The plasma supply unit 200 may excite a process gas to generate a plasma gas, thereby supplying the generated plasma gas onto the substrate W. The plasma supply unit 200 includes a reactor 210, an inducing coil 220, a power source 230, a gas injection port 240, and a process gas supply part 250.

The reactor 210 is disposed on the sealing cover 130. Also, the reactor 210 has a lower end coupled to an upper end of the sealing cover 130. The reactor 210 may have opened top and bottom surfaces and an inner space ES. The inner space ES of the reactor 210 may be provided as a discharge space in which plasma is generated. The reactor 210 have both ends connected to the gas injection port 240 and a lower end connected to the sealing cover 130.

The inducing coil 220 is wound around the reactor 210. The inducing coil 220 may be wound several times around the reactor 210. Also, the inducing coil has one end connected to the power source 230 and the other end that is grounded. The power source 230 applies a high-frequency power or microwave power to the inducing coil 220.

The gas injection port 240 is coupled to an upper end of the reactor 210 to supply the process gas into the discharge space ES. An inducing space IS is defined in a bottom surface of the gas injection port 240. The inducing space IS has an inverted hopper shape and is connected to the discharge space ES. The process gas introduced into the inducing space IS is diffused to move into the discharge space ES.

The process gas supply part 250 supplies the process gas into the discharge space ES. The process gas supply part 250 includes a process gas storage 251, a process gas supply line 252, and a valve 253.

The process gas storage 251 stores the process gas. The process gas may be a gas including at least one of oxygen (O₂), hydrogen (H₂), nitrogen (N₂), ammonia (NH₃), argon (Ar), and helium (He). The process gas supply line 252 connects the process gas storage 251 to the gas injection port 240. The process gas is supplied into the discharge space ES through the process gas supply line 252. The valve 253 is disposed in the process gas supply line 252. The valve 253 may adjust a flat rate of the process gas supplied through the process gas supply line 252.

The surface treating gas supply unit 300 supplies the surface treating gas into the treating space TS. The surface treating gas supply unit 300 includes a surface treating gas supply line 320, an inert gas storage 330, and an inert gas supply line 340.

A container 310 accommodates the surface treating material therein. The surface treating gas supply line 320 connects the process chamber 110 to the container 310. The surface treating gas supply line 320 is connected to the process chamber 110 at a height corresponding to that between the baffle 150 and the susceptor 140.

The inert gas supply line 340 connects the inert gas storage 330 to the container 310. The inert gas supply line 340 has one end that is immersed into the surface treating material within the container 310. An inert gas stored in the inert gas storage 330 is injected into the container 310 through the inert gas supply line 340. As the inert gas is injected into the container 310, an inner pressure of the container 310 may increase to supply the surface treating material having a gaseous state together with the inert gas into the process chamber 110 through the surface treating gas supply line 320. The inert gas may be a gas including at least one of argon (Ar), nitrogen (N₂), and helium (He).

Hereinafter, a method of treating inner surfaces of the baffle and the process chamber by using the above-described substrate treating apparatus will be described.

When the substrate treating apparatus 30 has a pause duration after being set or between the processes, the inside of the process chamber 110 may have a stable atmosphere. In this state, when the substrate treating process is performed, a substrate W may be damaged. Thus, the surface treating process may be performed before the surface treating process is actually performed.

The surface treating process may be performed as follows. First, the process gas is supplied from the process gas supply part into the discharge space ES. Then, a power is applied to the inducing coil 220 by using the power source 230 to generate induced magnetic fields. Thus, the process gas obtains energy required for ionization thereof from the induced magnetic fields and thus is excited into a plasma sate.

The plasma gas moves from the discharge space ES to the inducing space DS. Then, the plasma gas passes through the holes 152 of the baffle 150 and is introduced into a space between the baffle 150 and the susceptor 140.

While the plasma gas is introduced into the space between the baffle 150 and the susceptor 140, the surface treating gas supply unit 300 supplies a gas in which the surface treating gas and the inert gas are mixed into the process chamber 110. The surface treating gas obtains energy from the excited process gas and thus is excited in a plasma state to treat the inner surfaces of the baffle 150 and the process chamber 120. The surface treating gas may be supplied at a flow rate of about 1 cc/min to about 10 l/min. The flow rate of the surface treating gas may be supplied enough to treat the entire bottom surface of the baffle 150 and the entire inner surface of the process chamber 120. If the flow rate of the surface treating gas is too low, the plasma is insufficient. Thus, it may be difficult to achieve a surface treating effect. On the other hand, if the flow rate of the surface treating gas is too high, the activation of the plasma gas may be deteriorated. Thus, it may be difficult to achieve the surface treating effect.

When the surface treating process is finished, the supply of the surface treating gas is stopped. The gas staying in the process chamber 110 is exhausted through the exhaust line 170. After the surface treating process, the substrate W to be actually treated is loaded into the process chamber 110 and then is placed on the susceptor 140. Then, the process gas is supplied again into the discharge space ES. The process gas is discharged into the plasma state within the discharge space ES and then is supplied onto the substrate W. The plasma gas removes a photoresist film applied on the substrate W.

While the process is performed, the plasma gas contacts the surface of the baffle 150 and the inner surface of the process chamber 110. Since the aromatic compound provided for the surface treatment does not react with the active species and radicals, a flow rate of the active species and radicals may be constantly maintained. Thus, a large amount of active species and radicals may be supplied onto the substrate to improve an asking rate.

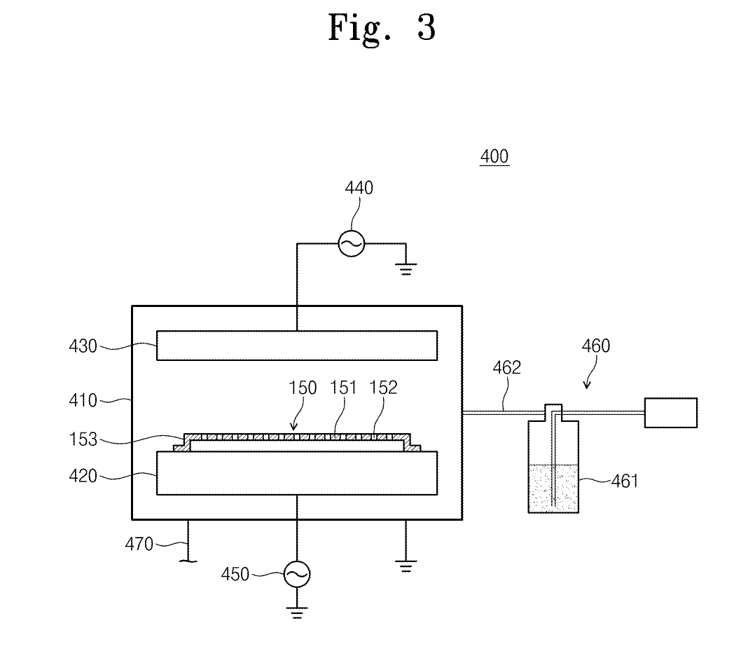

FIG. 3 is a view of a surface treating apparatus according to an embodiment of the present invention.

Referring to FIG. 3, a surface treating apparatus 400 performs a surface treating process on various devices provided in the above-described process chamber 110. In the current embodiment, the surface treating apparatus 400 performing a process of treating the surface of the baffle 150 will be described. The surface treating apparatus 400 includes a treating chamber 410, a support plate 420, an upper electrode 430, an upper power source 440, a lower power source, a surface treating gas supply unit 460, and an exhaust member 470.

The treating chamber 410 provides a space in which the process of treating the surface of the baffle 150 is performed. The support plate 420 is disposed within the treating chamber 410. The support plate 420 has a circular plate shape. Also, the support plate may have a radius corresponding to or greater than that of the baffle 150.

The baffle 150 is placed on the support plate 420. The baffle 150 is placed on the support plate 420 so that the coupling part 153 contacts a top surface of the support plate 420, and the bottom surface of the base 152 faces an upper side. The support plate 420 is provided as a lower electrode and electrically connected to the lower power source 450.

The upper electrode 430 is disposed above the support plate 420 to face the support plate 420. The upper electrode 430 is electrically connected to the upper power source 440. When a power is applied to the upper power source 440, an electric field is generated in a space between the upper electrode 430 and the support plate 420.

The exhaust member 470 is connected to the treating chamber 410. The exhaust member 470 adjusts an inner pressure of the treating chamber 410 and exhausts a gas staying in the treating chamber 410 to the outside.

The surface treating gas supply unit 460 supplies a surface treating gas into an inner space of the treating chamber 410. The surface treating gas supply unit 460 includes a container 461, a surface treating gas supply line 462, an inner gas storage 463, and an inner gas supply line 464.

A container 461 accommodates a surface treating material therein. The surface treating gas supply line 462 connects the treating chamber 410 to the container 461. The surface treating gas supply line 462 is connected to the treating chamber 410 in a region between the baffle 150 and the support plate 420. The inert gas supply line 464 connects the inert gas storage 463 to the container 461. An inert gas stored in the inert gas storage 463 is supplied into the container 461 through the inert gas supply line 464. As the inert gas is supplied into the container, an inner pressure of the container 461 may increase to supply the surface treating material having a gaseous state together with the inner gas into the treating chamber 410 through the surface treating gas supply-line 462. The surface treating gas and the inert gas are supplied into a space between the support plate 420 and the upper electrode 430.

When a power is applied to the upper electrode 430 to generate the electric field in a space between the upper electrode 430 and the support plate 420, the surface treating gas is excited in a plasma state. The excited surface treating gas is supplied into the baffle 150 to treat a surface of the baffle 150. Here, the inert gas may stabilize a state of the excited surface treating gas so that the surface of the baffle 150 is uniformly treated. In the above-described embodiment, the lower power source 450 may not be selectively provided.

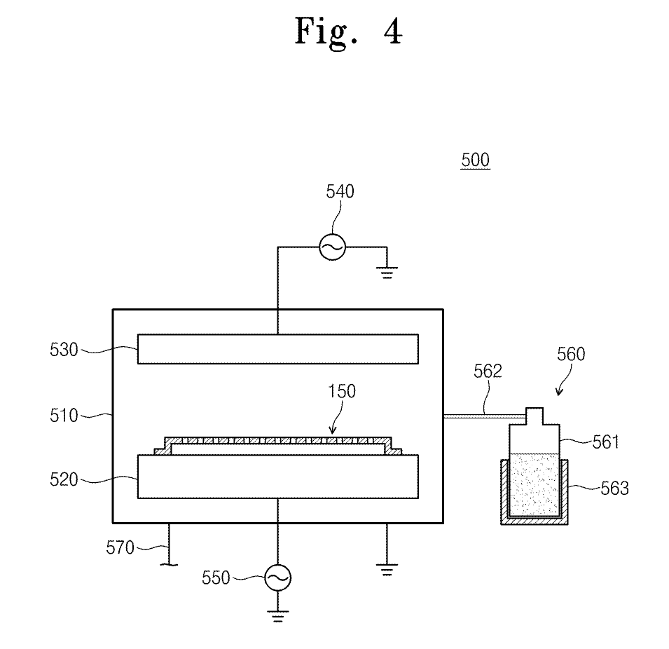

FIG. 4 is a view of a substrate treating apparatus according to another embodiment of the present invention. Referring to FIG. 4, unlike the surface treating gas supply unit 460 of FIG. 3, a surface treating gas supply unit 560 may heat a surface treating material stored in a container 561 to generate a surface treating gas. A heater 563 surrounds the container 561. When heat is generated by the heater 563, the surface treating gas is generated in the container 561. The surface treating gas is supplied into the treating chamber 510 through a surface treating gas supply line 562.

The surface treating gas supply unit 460 may be applied to the above-described substrate treating apparatus (see reference numeral 30 of FIG. 2) in the same method as the surface treating gas supply unit 300.

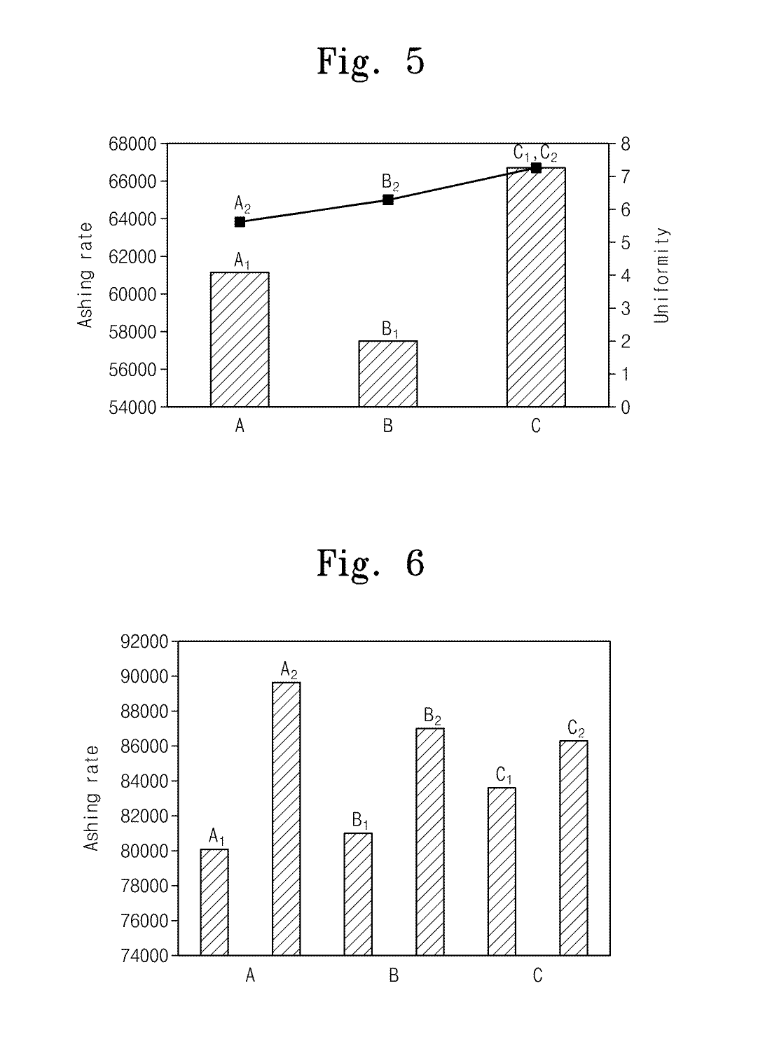

FIG. 5 is a graph illustrating ashing rates and uniformities of baffles having different surface states.

Referring to FIG. 5, a first result value A represents a result obtained by performing an ashing process by using a baffle of which a surface is not treated. According to the experimental result, it is seen that an ashing rate A1 is about 64,000 Å/mm, and uniformity A2 is about 6.

A second result value B represents a result obtained by performing an ashing process by using the baffle of which the surface is treated using an aliphatic compound. According to the experimental result, it is seen that an ashing rate B1 is about 57,000 Å/mm, and uniformity B2 is about 6.5.

A third result value C represents a result obtained by performing an ashing process by using the baffle of which the surface is treated using an aromatic compound. According to the experimental result, it is seen that an ashing rate C1 is about 67,000 Å/mm, and uniformity C2 is about 7.3.

Referring to the graph, it is seen that the ashing rate is improved when the ashing process is performed by using the baffle of which the surface is treated using the aromatic compound. This may represent that an amount of active species and radicals when the surface of the baffle is treated using the aromatic compound is relatively large when compared to that when the surface of the baffle is not treated or is treated using the aliphatic compound.

FIG. 6 is a graph illustrating ashing rates of a baffle according to surface treating materials before and after surface treatment.

Referring to FIG. 6, an experimental example 1(A) has a first result value A1 and a second result value A2. A first result A1 represents an ashing rate obtained by using a baffle of which a surface is not treated, and a second result A2 represents an ashing rate by using the baffle of which the surface is treated using an aromatic compound.

An experimental example 1(B) has a third result value B and a fourth result value B2. The third result B1 represents an ashing rate obtained by using the baffle of which the surface is not treated, and the fourth result B2 represents an ashing rate by using the baffle of which the surface is treated using a material containing the aromatic compound and an aliphatic compound.

An experimental example 3(C) has a fifth result value C1 and a sixth result value C2. The fifth result C1 represents an ashing rate obtained by using the baffle of which the surface is not treated, and the sixth result C2 represents an ashing rate by using the baffle of which the surface is treated using the aliphatic compound.

Since the experimental examples 1(A) to 3(C) is performed under different process conditions, the ashing rate obtained by using the baffle of which the surface is not treated in each of experiments, i.e., the first result value A1, the third result value B1, and the fifth result values C1 may have different values. Thus, it may be difficult to directly compare the results to each other. This represents to relatively compare the ashing rates to each other before and after the surface treatment is performed in each of the experimental examples.

In the experimental example 1(A), the ashing rate A2 after the surface treatment is improved by about 10,000 Å/mm than the ashing rate A1 before the surface treatment. In the experimental example 2(B), the ashing rate B2 after the surface treatment is improved by about 6,000 Å/mm than the ashing rate B1 before the surface treatment. In the experimental example 3(C), the ashing rate C2 after the surface treatment is improved by about 2,000 Å/mm than the ashing rate C1 before the surface treatment. The ashing rate is the highest in the experimental example 1(A) and is high in order of the experimental example 2(B) and the experimental example 3(C). This may represent that a relatively large amount of active species and radicals is supplied onto a substrate when the baffle is surface-treated by using the aromatic compound, and as the more an amount of the aliphatic compound increases, the more an amount of active species and radicals supplied onto the substrate decreases. In the experimental example 2(B), since the aliphatic compound is partially contained, the ashing rate may increase when compared to that in the experimental example 1(A).

According to the present invention, the reduction of the amount of the active species and radicals may be prevented to improve the ashing rate.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A baffle having holes for distributing a process gas excited in a plasma state, wherein a surface of the baffle is treated by using a surface treating material containing an aromatic compound.

2. The baffle of claim 1, wherein the baffle comprises:
a base in which the holes are defined; and
a coupling part having a ring shape, the coupling part protruding upward from an edge of a top surface of the base,
wherein the surface treating material is treated on a bottom surface of the base.

3. The baffle of claim 1, wherein the surface treating material further comprises an aliphatic compound.

4. The baffle of claim 1, wherein the aromatic compound comprises toluene.

5. The baffle of claim 1, wherein the surface-treated surface of the baffle is in a non-polarized state.

6. A substrate treating apparatus comprising:
a process camber having an inner space;
a susceptor disposed within the process chamber to support a substrate; and
a process gas supply unit supplying a process gas having a plasma state into the process chamber,
wherein an inner surface of the process chamber is treated by using a surface treating material comprising an aromatic compound.

7. The substrate treating apparatus of claim 6, wherein the surface treating material comprises an aliphatic compound.

8. The substrate treating apparatus of claim 6, wherein the surface-treated inner surface of the process chamber is in a non-polarized state.

9. The substrate treating apparatus of claim 6, further comprising a baffle disposed above the susceptor, the baffle having holes for distributing the process gas,
wherein a surface of the baffle is treated by using the surface treating material.

10. The substrate treating apparatus of claim 9, wherein a bottom surface of the baffle facing the substrate is treated.

11. The substrate treating apparatus of claim 6, wherein the surface-treated inner surface of the process chamber is in a non-polarized state.

12. An apparatus for treating a surface of a baffle, the apparatus comprising:
a treating chamber having an inner space;
a support plate on which a baffle is placed, the support plate being disposed within the treating chamber and provided as a lower electrode;
an upper electrode disposed above the support plate to face the support plate, the upper electrode generating an electric field in a space between the support plate and the upper electrode; and
a surface treating gas supply unit supplying a surface treating gas comprising an aromatic compound into the space between the support plate and the upper electrode,
wherein the surface treating gas is excited in a plasma state by the electric field to treat a surface of the baffle.

13. The apparatus of claim 12, wherein the baffle comprises:
a base in which holes are defined; and
a coupling part having a ring shape, the coupling part protruding upward from an edge of a top surface of the base,
wherein the baffle is placed on the support plate so that a bottom surface of the base faces the upper electrode.

14. The apparatus of claim 12, wherein the surface treating gas supply unit comprises:
a container storing a surface treating material comprising the aromatic compound;
an inert gas supply part injecting an inert gas into the container to press the inside of the container; and
a gas supply line connecting the treating chamber to the container, the gas supply line supplying the surface treating gas generated in the container into the treating chamber.

15. The apparatus of claim 12, wherein the surface treating gas supply unit comprises:
a container storing a surface treating material comprising the aromatic compound;
a heater heating the inside of the container; and
a gas supply line connecting the treating chamber to the container, the gas supply line supplying the surface treating gas generated in the container into the treating chamber.

16. The apparatus of claim 12, wherein the surface treating gas further comprises an aliphatic compound.

17. The apparatus of claim 12, further comprising an exhaust member connected to the treating chamber to exhaust a gas within the treating chamber to the outside.

18. A surface treating method in which a process gas excited in a plasma state is supplied toward a baffle mounted in a process chamber, and while the excited process gas passes through holes of the baffle to stay in a space between the baffle and a susceptor on which a substrate is placed, a surface treating gas comprising an aromatic compound is supplied into the space between the baffle and the susceptor to treat a surface of the baffle and an inner surface of the process chamber.

19. The surface treating method of claim 18, wherein the surface treating gas further comprises an aliphatic compound.

20. The surface treating method of claim 18, wherein the surface treating gas is supplied at a flow rate of about 1 cc/min to about 10 l/min.
